(19) United States
(12) Patent Application Publication
(10) Pub. No.: US 2011/0307911 A1
(43) Pub. Date: Dec. 15, 2011

(54) CIRCUIT BOARD, MOTOR, DISK DRIVE APPARATUS AND CIRCUIT BOARD MANUFACTURING METHOD

(75) Inventors: Masahiro Yamada, Kyoto (JP); Satoshi Komatsu, Kyoto (JP)

(73) Assignee: NIDEC CORPORATION, Kyoto (JP)

(21) Appl. No.: 13/154,689

(22) Filed: Jun. 7, 2011

Related U.S. Application Data
(60) Provisional application No. 61/344,202, filed on Jun. 9, 2010.

(51) Int. Cl. G11B 17/00; H02K 11/00; H05K 3/34; H05K 7/06

(52) U.S. Cl. 720/703; 361/777; 310/68 B; 310/68 D; 310/71; 29/840; G9B/17

(57) ABSTRACT

A circuit board for supplying therethrough an electric current to a stator including windings arranged to generate magnetic fields includes a body portion having a rectangular shape when seen in a plan view and mounted with electronic parts, and an extension portion protruding from the body portion substantially along a circumferential direction around a rotation axis of the motor when seen in a plan view. The extension portion includes a distal end extension opposed to the body portion through a gap when seen in a plan view. The transverse width of the extension portion is smaller than the gap. The body portion includes an outward connector portion connected to an external power source or an external circuit board. The extension portion includes a winding connection portion connected to the outward connector portion through a wiring portion. The windings are soldered to the winding connection portion.

### BACKGROUND OF THE INVENTION

1. Field of the Invention

The present invention relates to a circuit board used in a motor for a disk drive apparatus for driving an optical disk such as a CD or a DVD, a motor provided with the circuit board, a disk drive apparatus provided with the motor and a circuit board manufacturing method.

2. Description of the Related Art

A disk drive apparatus is mounted with a removable disk rotated by a motor. Examples of the removable disk include a CD, a DVD and a Blu-ray disk.

The motor is connected to a circuit board. Various kinds of electronic parts such as a driving IC and a connector are mounted on the circuit board. The connector is used in electrically interconnecting an actual device and the motor. In case of a three-phase motor, three kinds of U-phase, V-phase and W-phase conductor wires are wound around a stator core. The conductor wires are connected to the circuit board by soldering.

In recent years, an increasing demand exists for a small-size and low-profile motor for use in a disk drive apparatus. In view of this, an attempt to reduce the size of a circuit board to which a motor is connected has been made by densely arranging electronic parts on the circuit board and reducing the electronic-part mounting area of the circuit board.

Due to the increased mounting density, however, the electronic parts are arranged near the positions where conductor wires are soldered to a circuit board. As a result, it is sometimes the case that, depending on the positions of the electronic parts and the soldering positions, solder may adhere to the electronic parts when the conductor wires are soldered to the circuit board by a worker. In case where soldering points are positioned along a straight line near the electronic parts, it is necessary for a worker to use a jig to avoid physical contact with the electronic parts. This tends to deteriorate the workability.

### SUMMARY OF THE INVENTION

In accordance with an embodiment of the present invention, there is provided a circuit board for supplying therethrough an electric current to a stator that includes windings arranged to generate magnetic fields for rotation of a motor, including: a body portion having a substantially rectangular shape when seen in a plan view and mounted with electronic parts; and an extension portion protruding in an arc-shape from the body portion along a circumferential direction around a rotation axis of the motor when seen in a plan view, wherein the extension portion includes a distal end extension opposed to the body portion through a gap when seen in a plan view, the transverse width of the extension portion as seen in a plan view being smaller than the gap, the body portion including an outward connector portion electrically connected to an external power source or an external circuit board, the extension portion including a winding connection portion connected to the outward connector portion through a wiring portion, the windings being soldered to the winding connection portion.

### BRIEF DESCRIPTION OF THE DRAWINGS

FIG. 1 is a schematic view showing a disk drive apparatus in accordance with an embodiment of the present invention.

FIG. 2 is a section view showing a motor provided with a circuit board according to the embodiment of the present invention.

FIG. 3 is a plan view showing the circuit board according to the embodiment of the present invention.

FIG. 4 is a plan view showing a parent board for the manufacture of the circuit board according to the embodiment of the present invention.

FIG. 5 is a plan view showing one modified example of the circuit board according to the embodiment of the present invention.

FIG. 6 is a plan view showing another modified example of the circuit board according to the embodiment of the present invention.

FIG. 7 is a plan view showing a further modified example of the circuit board according to the embodiment of the present invention.

### DESCRIPTION OF THE PREFERRED EMBODIMENTS

In the subject specification, the upper side in the direction of a center axis of a motor will be just referred to as “upper” and the lower side as “lower”. However, these definitions are not intended to indicate the upper and lower directions when the present disk drive apparatus is assembled to actual devices. In addition, the direction running circumferentially about the center axis will be just referred to as “circumferential” and the direction running radially about the center axis will be just referred to as “radial”.

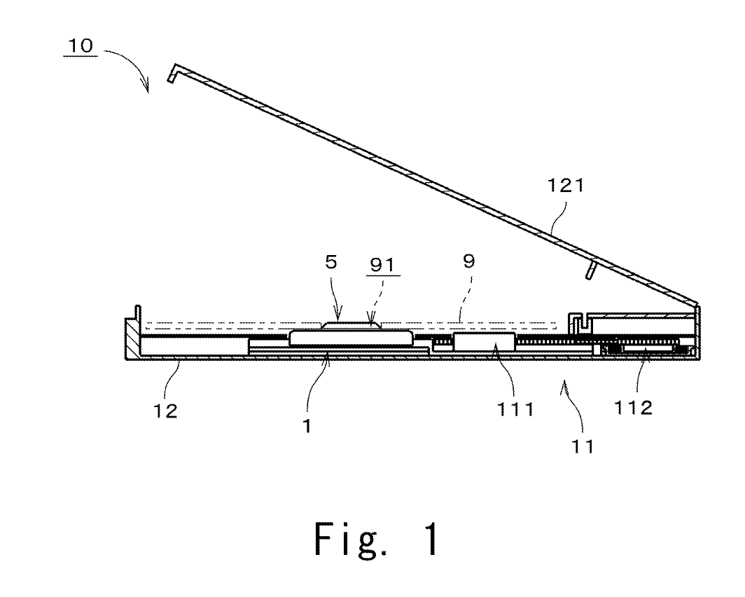

Referring to FIG. 1, a disk drive apparatus 10 preferably includes a motor 1, an access unit 11 and a box-shaped housing 12 arranged to accommodate the motor 1 and the access unit 11. The motor 1 is of a low-profile motor having a height of from several millimeters to several tens millimeters. In the motor 1, a central opening 91 of a recording disk 9 is fitted to a chucking device 5 to be described later, whereby the recording disk 9 is fixed to the motor 1.

The access unit 11 preferably includes a head 111 and a head moving mechanism 112. The head 111 is an optical pickup mechanism and performs information reading and/or writing tasks with respect to the recording disk 9. A removable disk, such as a CD, a DVD, a Blu-ray disk or the like, is used as the recording disk 9. Other kinds of disks may be used as the recording disk 9.

The head moving mechanism 112 serves to move the head 111 with respect to the motor 1 and the recording disk 9. The head 111 preferably includes a light emitting unit and a light receiving unit. The light emitting unit emits laser light toward the lower surface of the recording disk 9. The laser light is reflected by the recording disk 9. The light receiving unit receives the light reflected from the recording disk 9. The housing 12 preferably includes a lid 121 arranged in the upper portion thereof. The lid 121 is opened and closed when the recording disk 9 is attached into or removed from the disk drive apparatus 10. With this disk drive apparatus 10, the recording disk 9 is rotated by the motor 1. The head moving mechanism 112 moves the head 111 to a desired position. The head 111 performs information reading and/or writing tasks with respect to the recording disk 9.

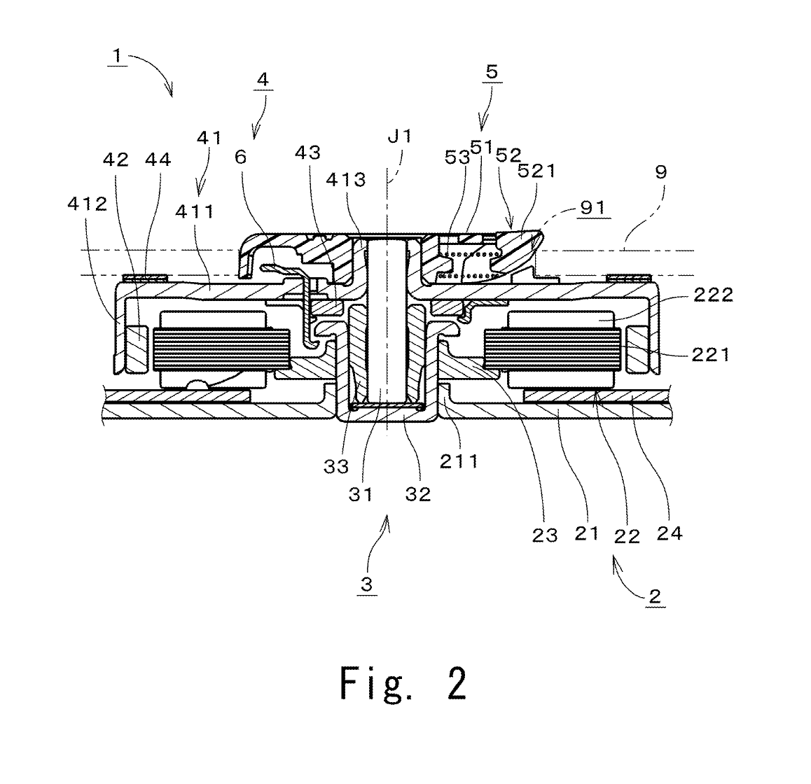

FIG. 2 is a vertical section view of the motor 1, in which view the recording disk 9 is depicted by double-dotted lines. Referring to FIG. 2, the motor 1 preferably includes a stationary unit 2, a bearing unit 3, a rotary unit 4 and a chucking device 5, the former two of which form a fixed assembly and the latter two of which form a rotating assembly. The rotary unit 4 is positioned to surround the stationary unit 2 and the bearing unit 3. The bearing unit 3 supports the rotary unit 4 so that the rotary unit 4 can rotate about a rotation axis J1 with respect to the stationary unit 2. The chucking device 5 is arranged above the rotary unit 4.

The stationary unit 2 preferably includes an attachment plate 21, a stator 22, a stator holding member 23 and a circuit board 24. The attachment plate 21 is made of, e.g., metal. A cylindrical bearing holder 211 is provided in the central area of the attachment plate 21. The bearing unit 3 is attached to the bearing holder 211. The stator 22 is arranged radially outward of the bearing unit 3 and preferably includes a stator core 221 and a plurality of coils 222 wound around the stator core 221. The stator core 221 is formed of laminated steel plates. The laminated steel plates are formed by laminating a plurality of electromagnetic steel plates having a specified shape one above another. The circuit board 24 is arranged on the attachment plate 21. The stator holding member 23 has an annular shape. The stator holding member 23 is arranged around the bearing unit 3 and positioned lower than the upper end of the stator 22. In the stationary unit 2, the stator core 221 is arranged at the outer circumference of the stator holding member 23. Thus, the stator 22 is indirectly fixed to the bearing unit 3.

The bearing unit 3 preferably includes a bush 32 and a bearing member 33. The bush 32 has a substantially cylindrical shape having a bottom portion. The bush 32 is fixed to the bearing holder 211 by press-fit. An annular recess is defined in the radial outer area of the bottom portion of the bush 32. A flange portion extending radially outward is formed at the open end of the bush 32 opposite to the through-hole defined in the attachment plate 21. A fixing area where the stator holding member 23 and the bush 32 are fixed to each other is positioned axially below the flange portion.

The bearing member 33 is inserted into the bush 32. In the present preferred embodiment, a sleeve bearing is used as the bearing member 33 and the sleeve bearing is fixed to the bush 32 by press-fit. The sleeve bearing is made of, e.g., porous sintered metal, and is impregnated with a lubricant. The inner diameter of the axial middle portion of the bearing member 33 is set greater than the inner diameter of the axial upper and lower portions thereof. The axial middle portion of the bearing member 33 is opposed to the outer circumferential surface of a shaft 31 with a gap left therebetween. This makes it possible to stably support the shaft 31 in a radial direction. A thrust plate is arranged on the bottom portion of the bush 32. This makes it possible to stably support the shaft 31 in a thrust direction.

The rotary unit 4 preferably includes a rotor holder 41, a rotor magnet 42, a pre-load magnet 43, an annular rubber member 44 and an annular removal-preventing member 6.

The rotor holder 41 has a substantially cylindrical shape having a top portion and covers the stator 22. The rotor holder 41 is made of, e.g., a magnetic material. The rotor holder 41 preferably includes a cover portion 411, a cylinder portion 412 and a cylindrical shaft-fixing portion 413. The cover portion 411 serves as a disk support portion 411 on which the recording disk 9 is placed. The shaft-fixing portion 413 is a substantially cylindrical portion protruding axially upward from the substantially central area of the cover portion 411. The upper end portion of the shaft 31 is inserted into, and fixed to, the shaft-fixing portion 413. An annular recess is defined on the inner circumferential surface of the shaft-fixing portion 413. An adhesive agent is interposed between the shaft 31 and the shaft-fixing portion 413. The adhesive agent also exists in the annular recess. Accordingly, the shaft 31 is stably fixed to the shaft-fixing portion 413. The shaft 31 and the shaft-fixing portion 413 may be fixed to each other by bonding, press-fitting or both.

A plurality of through-holes is defined in the cover portion 411. The removal-preventing member 6 preferably includes an annular portion provided with a plurality of axially upwardly protruding lugs. The lugs are respectively inserted into the through-holes of the cover portion 411. The lugs are fixed to the cover portion 411 by bending and caulking the tip ends of the lugs. The lugs may be fixed to the cover portion 411 by an adhesive agent.

First hook portions and second hook portions are formed in the annular portion of the removal-preventing member 6. Each of the first hook portions extends axially downward and has a hook-shaped tip end. The tip ends of the first hook portions are axially opposed to the flange portion of the bush 32. The second hook portions have hook-shaped tip ends and hold the pre-load magnet 43 in place. The pre-load magnet 43 is opposed to the cover portion 411 and also axially opposed to the flange portion of the bush 32.

With such configurations, a removal stop of the rotary unit 4 is provided by the pre-load magnet 43 and the removal-preventing member 6. This prevents the rotary unit 4 from axially moving away from the stationary unit 2.

The disk support portion 411 is substantially perpendicular to the center axis J1 and extends outwards around the chucking device 5. The rubber member 44 is provided in the radial outer area of the upper surface of the disk support portion 411. The recording disk 9 is indirectly supported on the disk support portion 411 through the rubber member 44.

The chucking device 5 preferably includes a center case 51, a plurality of claw members 52, a plurality of coil springs 53 and a plurality of centering claws. In the present preferred embodiment, the number of the claw members 52, the coil springs 53 and the centering claws are three, respectively. The center case 51 is a disc-shaped hollow member concentric with the center axis J1. On the outer circumferential surface of the center case 51, a plurality of radially extending through-holes is defined in a corresponding relationship with the claw members 52. The claw members 52 are arranged along a circumferential direction and protrude radially outward from the outer circumferential surface of the center case 51 through the respective through-holes. The coil springs 53 are arranged within the center case 51. A protrusion is provided at the radial inner side of each of the claw members 52. Each of the coil springs 53 is supported at one end by the protrusion of each of the claw members 52 and at the other end by a support member provided within the center case 51. The coil springs 53 serve to bias the claw members 52 radially outward. The coil springs 53 are elastically deformable by the attachment and removal of the recording disk 9. In the motor 1, a rubber member or other elastic members may be used in place of the coil springs. Each of the centering claws is arranged between two circumferentially adjoining claw members 52.

During the course of fixing the recording disk 9 on the disk support portion 411, the recording disk 9 makes contact with claw bodies 521 of the claw members 52. Consequently, the claw bodies 521 are slightly rotated clockwise in FIG. 2 and moved radially inwards. The recording disk 9 is placed on the disk support portion 411 with the center thereof being brought into alignment with the rotation axis J1 by the centering claws. At this time, as shown in FIG. 2, the tip ends of the claw bodies 521 move to the upper side of the recording disk 9 and the claw members 52 are pressed by the coil springs 53 to move back radially outward. The claw members 52 make contact with the upper edge of the central opening 91 of the recording disk 9. In this manner, the tip ends of the claw bodies 521 of the chucking device 5 are movable in the vertical direction and the radial direction. The recording disk 9 is biased radially outward and downward by the claw members 52 and eventually fixed on the disk support portion 411.

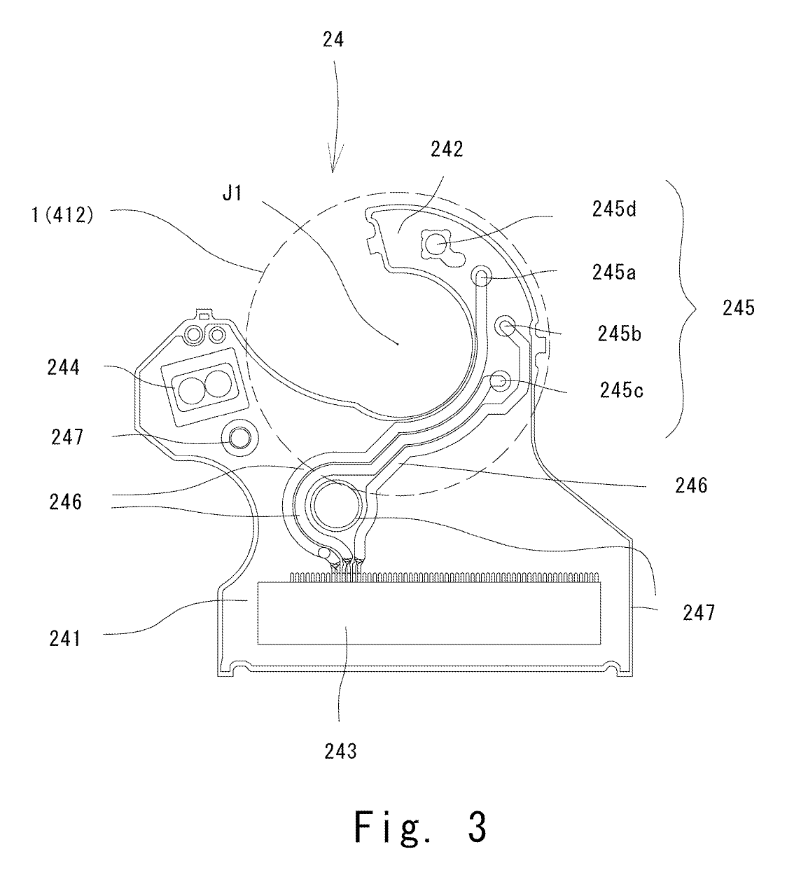

Referring to FIG. 3, the contour of the rotor holder is indicated by a broken line. The circuit board 24 preferably includes a body portion 241 and an arc portion 242 protruding in an arc shape from the body portion 241. The stator 22 and the bush 32 are positioned inside the area surrounded by the broken line (near the center axis J1). The arc portion 242 is arranged radially inward of the contour of the rotor holder 41. The arc portion 242 is shaped to conform to the contour of the rotor holder 41. In other words, the arc portion 242 is an extension portion protruding from the body portion 241 along the circumferential direction of the rotation axis J1 of the motor 1 when seen in a plan view.

Various kinds of electronic parts (e.g., a connector 243 and a photo sensor 244) are mounted to, and densely arranged on, the body portion 241. This makes it possible to reduce the mounting area of electronic parts in the circuit board 24 and to reduce the size of the circuit board 24. The bush 32 and the bearing holder 211 are arranged radially inward of the arc portion 242. The outer circumferential surface of the arc portion 242 is positioned inside the contour of the motor 1 (on the side of the center axis J1).

The connector 243 serves as an outward connector unit connected to an external power source. An electric current is supplied to the circuit board 24 and the motor 1 through the connector 243. The body portion 241 preferably includes a substantially rectilinear contour portion opposed to the arc portion 242. The connector 243 is arranged substantially parallel to the longitudinal direction of the rectilinear contour portion. The rectilinear contour portion is formed longer than the longitudinal dimension of the connector 243. In the present preferred embodiment, the longitudinal dimension of the connector 243 is set longer than the arc portion 242.

The photo sensor 244 serves to detect the rotation speed of the recording disk 9. In particular, the photo sensor 244 is capable of accurately detecting the rotation speed of the recording disk 9 when the rotary unit 4 of the motor 1 rotates at a reduced speed (e.g., about 40 rpm to 100 rpm). The photo sensor 244 is fixed to the body portion 241 through a resin-made base portion. The photo sensor 244 may be directly mounted to the body portion 241.

Wiring patterns are formed on, and other electronic parts are mounted to, the areas of the body portion 241 not mounted with the connector 243 and the photo sensor 244.

The arc portion 242 extends from the body portion 241 in an arc shape along the circumferential direction around the rotation axis J1.

In the present preferred embodiment, the motor 1 is a three-phase motor. Therefore, four wires corresponding to the U-phase, V-phase, W-phase and the common are drawn out from the coils 222. Winding connection portions 245 are provided at four points in the arc portion 242. The four wires are fixed to the winding connection portions 245 by soldering. In other words, the winding connection portions 245a, 245b, 245c and 245d correspond to the U-phase, V-phase, W-phase and the common of the motor 1. The winding connection portions 245a, 245b and 245c are connected to the connector 243 through wiring portions 246. The winding connection portions 245a, 245b and 245c are arranged along the extension direction of the arc portion 242. The order of arranging the winding connection portions 245a, 245b and 245c is not particularly limited but may be arbitrary. The winding connection portions 245a, 245b, 245c are arranged in an axially opposing relationship with the motor 1. At least some of the wiring portions 246 are arranged along the arc portion 242.

Naked portions 247 applied with no resist ink are formed in the peripheral edge of the circuit board 24.

Next, description will be made on a method for manufacturing the motor 1 provided with the circuit board of the present preferred embodiment.

First, electronic parts such as the connector 243 and the photo sensor 244 are mounted to the circuit board 24 (step 1).

Then, the circuit board 24 is attached to the motor 1 (step 2). At this time, the attachment plate 21, the bush 32 and the bearing member 33 are fixed to the motor 1 in advance. In addition, the stator 22 and the chucking device 5 and the like are separately assembled beforehand.

The circuit board 24 is fixed to the attachment plate 21 of the motor 1 through an insulating adhesive agent (step 3). The circuit board 24 and the attachment plate 21 may be fixed to each other by a method of forming burrs on the attachment plate 21 and caulking the attachment plate 21 to the circuit board 24 (a so-called burr caulking method).

Next, the stator 22 is assembled to the bush 32 (step 4). As described above, the stator 22 includes the coils 222 formed by winding conductor wires. Four conductor wires of the U-phase, V-phase, W-phase and the common are drawn out from the stator 22. The bush 32 and the stator 22 are fixed to each other through the stator holding member 23 coupled to the stator 22 by an adhesive agent.

Then, the four conductor wires drawn out from the stator 22 are soldered to the winding connection portions 245a, 245b, 245c and 245d, respectively (step 5). At this time, the soldering worker conducts the soldering of the respective conductor wires from the right side in FIG. 3.

In other words, the worker can bring, e.g., jigs into contact with the winding connection portions 245a, 245b, 245c and 245d from the outer circumference of the arc portion 242 toward the inner circumference thereof without encroaching on the area where electronic parts are arranged with an increased density.

The conventional circuit board does not have the arc portion 242 of the present invention so that the respective winding connection portions are arranged in the body portion in the conventional circuit board. Therefore, if a worker conducts soldering on the conventional circuit board from the right side in FIG. 3 to avoid the connector, the stator or the bush 32 hinders the soldering work and impair the workability. If the soldering is conducted from the lower side in FIG. 3, solder balls are scattered away and may possibly adhere to the electronic parts such as the connector and the like. When conducting the soldering from the lower side in FIG. 3, there is a method of preventing adherence of the solder balls to the electronic parts by covering the electronic parts with a jig. In this method, however, the shape of the jig becomes complex because the soldering points exist near the electronic parts. Moreover, the workability grows worse because additional steps are required to attach and detach the jig.

In contrast, in the circuit board 24 of the present embodiment, the winding connection portions 245a, 245b, 245c and 245d are arranged in the arc portion 242. This makes it possible to solder the conductor wires to the winding connection portions 245a, 245b, 245c and 245d from the right side in FIG. 3 with no interference with the electronic parts such as the connector 243 or the like. The number of the electronic parts arranged around the arc portion 242 is smaller than the number of the electronic parts disposed in the body portion 241. Therefore, even when the solder balls are scattered during the soldering work, it is less likely that the solder balls adhere to the electronic parts. Even if the jig covers the electronic parts to prevent adherence of the solder balls to the electronic parts, the workability is not worsen because the soldering points are spaced apart from the jig.

Finally, the shaft 31 fixed to the rotary unit 4 is inserted into the bearing unit 33 (step 5). At this time, the chucking device 5 is fixed to the rotary unit 4 in advance. The motor 1 is completely fabricated through the steps set forth above.

Next, description will be made on the parent board 6 of the circuit board 24 according to the present embodiment.

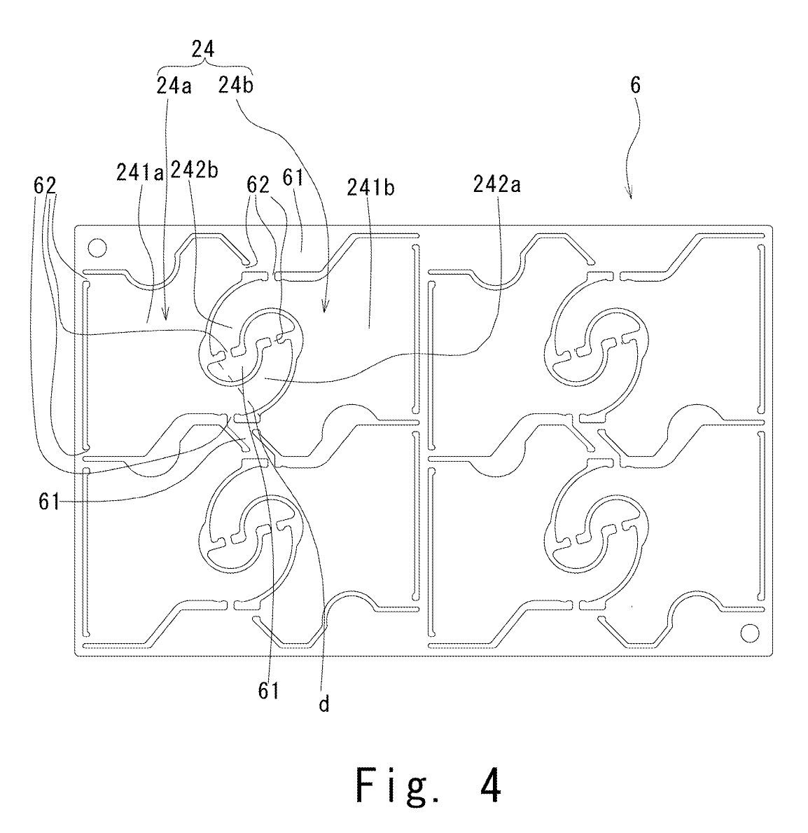

Referring to FIG. 4, the parent board 6 preferably includes a plurality of circuit boards 24, a plurality of waste boards 61 and a plurality of severance portions 62. In the parent board 6, the circuit boards 24 and the waste boards 61 are formed so that they can be interconnected into one piece. When seen in a plan view, the circuit boards 24 and the waste boards 61 are connected to each other through the severance portions 62. Resist ink is applied on the circuit boards 24. However, the severance portions 62 are applied with no resist ink. At least one through-hole is defined in the corner area of the parent board 6. In the present preferred embodiment, two through-holes are defined in the corner areas of the parent board 6 in a diagonally opposing relationship with each other. The through-holes are used, e.g., when the parent board 6 is fixed to a jig or the like. The waste boards 61 are separated from the circuit board 24 in the manufacture of the circuit boards 24.

In the present preferred embodiment, eight circuit boards 24 can be manufactured from one parent board 6. For the sake of convenience in description, only two circuit boards 24a and 24b positioned in the left upper portion of the parent board 6 in FIG. 4 will be described herein below. The circuit board positioned in the left upper portion in FIG. 4 will be referred to as “first circuit board 24a”, and the circuit board positioned at the right side of the first circuit board 24a will be referred to as “second circuit board 24b”.

In FIG. 4, the arc portion 242a of the first circuit board 24a is partially situated within a gap through which the body portion 241b and the arc portion 242b of the second circuit board 24b are opposed to each other (namely, at the right upper side of a broken line d). The severance portions 62 are arranged around the contour of the first circuit board 24a and the second circuit board 24b.

In other words, the outer surface of the arc portion 242a of the first circuit board 24a is opposed to the inner surface of the arc portion 242b of the second circuit board 24b through the severance portions 62. Moreover, the outer surface of the arc portion 242a is opposed to the body portion 241b of the second circuit board 24b through the severance portions 62.

Similarly, the outer surface of the arc portion 242b of the second circuit board 24b is opposed to the inner surface of the arc portion 242a of the first circuit board 24a through the severance portions 62. Moreover, the outer surface of the arc portion 242b is opposed to the body portion 241a through the severance portions 62.

By forming the parent board 6 as set forth above, it is possible to increase the area and number of the first circuit boards 24a and the second circuit boards 24b in the parent board 6 and to reduce the area of the waste boards 61. As a result, it is possible to manufacture an increased number of circuit boards 24 from one parent board 6.

Next, description will be made on the process of manufacturing the circuit boards 24 from the parent board 6.

First, electronic parts such as the connector 243 and the photo sensor 244 are mounted to the circuit boards 24 (step 1). By mounting the electronic parts in a state that the circuit boards 24 are not separated from the parent board 6, it becomes possible to simultaneously mount the electronic parts to all the circuit boards 24.

Then, the parent board 6 is put into a reflow furnace and the respective electronic parts are soldered to the circuit boards 24 (step 2). By putting the parent board 6 mounted with the electronic parts into the reflow furnace, it becomes possible to simultaneously solder the electronic parts to all the circuit boards 24.

Finally, the severance portions 62 are cut to sever the circuit boards 24 carrying the electronic parts soldered thereto and the waste boards 61 from the parent board 6 (step 3), thereby producing the circuit boards 24.

As mentioned earlier, no resist ink is applied to the severance portions 62. Therefore, if the severance portions are severed from the parent board 6, the severance portions 62 become the end portions of the circuit boards 24. In other words, naked portions 247 (see FIG. 3) applied with no resist ink are formed in the end portions of the circuit boards 24 by cutting the severance portions 62. By not applying resist ink to the severance portions 62, it is possible to prevent the resist ink applied on the circuit boards 24 from being broken during the course of severing the circuit boards 24 from the parent board 6. Accordingly, it is possible to prevent occurrence of poor connection in the circuit boards 24 which would otherwise occur when the resist ink is broken and the fragments thereof as foreign materials are infiltrated into the connector 243.

While one preferred embodiment of the present invention has been described above, the present invention is not limited to this embodiment but may be modified in many different forms.

In the structure shown in FIG. 3, the circuit board 24 is not arranged in the axial gap between the attachment plate 21 and the motor 1, namely in the spatial area between the tip end of the arc portion 242 and the body portion 241. In other words, the motor 1 is directly opposed to the attachment plate 21 in the spatial area between the tip end of the arc portion 242 and the body portion 241.

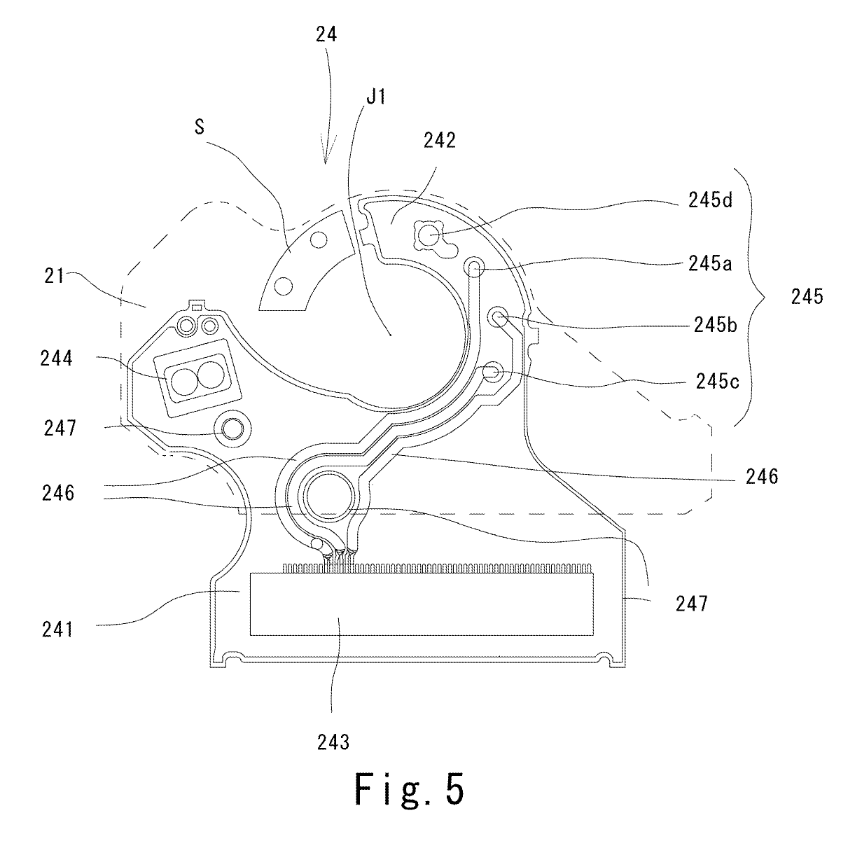

As shown in FIG. 5, a substantially arc-shaped spacer S may be arranged on the attachment plate 21 between tip end of the arc portion 242 and the body portion 241. The spacer S is directly opposed to the motor 1 in the spatial area between the tip end of the arc portion 242 and the body portion 241. This helps reduce the axial gap between the motor 1 and the attachment plate 21. As a result, it is possible to prevent foreign materials from infiltrating into the motor 1.

The spacer S has a plurality of through-holes. In FIG. 5, two through-holes are defined in the spacer S. The attachment plate 21 has a plurality of axially-extending bur portions. In the present embodiment, two burr portions are formed in the attachment plate 21. As the burr portions are inserted into the through-holes of the spacer S, the position of the spacer S is determined with respect to the attachment plate 21. The spacer S is fixed to the attachment plate 21 by, e.g., an adhesive agent, an adhesive tape or caulking by which the burr portions are crushed. In place of the burr portions, raised portions may be formed on the attachment plate 21 by plastic working (e.g., half blanking). In this case, the position of the spacer S is determined with respect to the attachment plate 21 as the raised portions are inserted into the through-holes of the spacer S.

Instead of the spacer S, at least one axially-protruding lug may be formed in the attachment plate 21 between the tip end of the arc portion 242 and the body portion 241 by plastic working (e.g., half blanking). This makes it possible to reduce the axial gap between the motor and the attachment plate 21 and to prevent foreign materials from infiltrating into the motor 1.

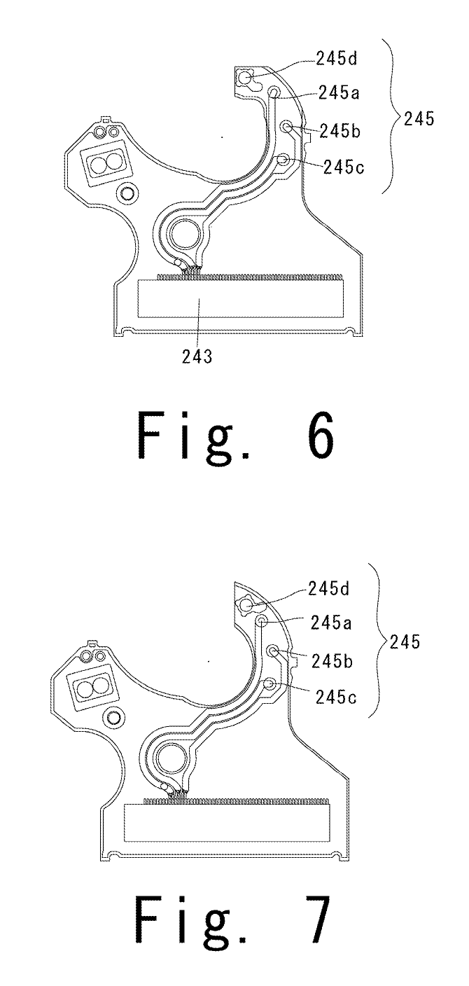

The arc portion 242 does not necessarily have an arc shape. For example, as shown in FIG. 6, the extension portion may have a hook shape. Alternatively, the extension portion may have a rectilinear shape as shown in FIG. 7. The arc portion 242 may have a reduced length. It will be all right if electronic parts such as the connector 243 and the like do not exist at least in the area defined by the open angle extension lines joining the respective winding connection portions to the center axis J1. Further, the arc portion 242 may extend from the left side of the center axis J1 to the right side in FIG. 3.

What is claimed is:

1. A circuit board for supplying therethrough an electric current to a stator that includes windings arranged to generate magnetic fields for rotation of a motor, comprising:
a body portion having a substantially rectangular shape when seen in a plan view and mounted with electronic parts; and
an extension portion protruding from the body portion substantially along a circumferential direction around a rotation axis of the motor when seen in a plan view,
wherein the extension portion includes a distal end extension opposed to the body portion through a gap when seen in a plan view, the transverse width of the extension portion as seen in a plan view being smaller than the gap, the body portion including an outward connector portion electrically connected to an external power source or an external circuit board, the extension portion including a winding connection portion connected to the outward connector portion through a wiring portion, the windings being soldered to the winding connection portion.

2. The circuit board of claim 1, wherein the wiring portion is at least partially arranged along the extension portion.

3. The circuit board of claim 1, wherein no resist ink is applied on a peripheral edge of the circuit board.

4. The circuit board of claim 1, wherein the outward connector portion has a longitudinal dimension longer than the extension portion.

5. The circuit board of claim 1, further comprising a photo sensor arranged in the body portion in an axially opposing relationship with a disk rotationally driven by the motor.

6. The circuit board of claim 1, wherein the extension portion is an arc portion protruding in an arc shape along the circumferential direction.

7. A motor, comprising:
an attachment plate extending perpendicularly to a rotation axis and attached to an apparatus body;
a circuit board fixed to the upper side of the attachment plate;
a stationary unit arranged above the circuit board, the stationary unit including a stator arranged to generate magnetic fields for rotation of the motor when an electric current flows through windings;
a rotor holder arranged to surround the stator;
a rotary unit fixed inside the rotor holder, the rotary unit including a rotor magnet opposed to the stator in a spaced-apart relationship; and
a bearing unit arranged to rotatably support the rotary unit with respect to the stationary unit,
wherein the circuit board includes a body portion having a substantially rectangular shape when seen in a plan view and mounted with electronic parts and an arc portion protruding in an arc-shape from the body portion along a circumferential direction around the rotation axis when seen in a plan view, the arc portion arranged to surround the bearing unit when seen in a plan view, the arc portion including a distal end extension opposed to the body portion through a gap when seen in a plan view, the transverse width of the arc portion as seen in a plan view being smaller than the gap, the body portion including an outward connector portion electrically connected to an external power source or an external circuit board, the arc portion including a plurality of winding connection portions connected to the outward connector portion through a wiring portion, the windings being soldered to the winding connection portions, the winding connection portions being positioned radially inwards of an outer circumferential surface of the rotor holder.

8. The motor of claim 7, wherein the arc portion is formed into a shape conforming to a contour of the motor.

9. The motor of claim 7, wherein the body portion includes a rectilinear contour portion opposed to the arc portion, the rectilinear contour portion being longer than a longitudinal dimension of the outward connector portion.

10. The motor of claim 7, further comprising a substantially arc-shaped spacer arranged on the attachment plate between a tip end of the arc portion and the body portion, the spacer being axially opposed to the motor.

11. The motor of claim 7, wherein the attachment plate includes at least one axially-protruding raised portion arranged between a tip end of the arc portion and the body portion.

12. The motor of claim 7, further comprising a plurality of conductor wires drawn out from the stator, the conductor wires being connected to the winding connection portions by soldering.

13. The motor of claim 10, wherein the stator is a stator for a three-phase motor, and at least three conductor wires are drawn out from the stator and connected to the winding connection portions.

14. The motor of claim 7, wherein the winding connection portions are arranged in an axially opposing relationship with the stator.

15. The motor of claim 7, wherein the winding connection portions are arranged along an extension direction of the arc portion.

16. A disk drive apparatus, comprising:
the motor of claim 7 arranged to rotate a recording disk;
a chucking device arranged to rotate together with the motor;
an access unit arranged to perform at least one of information reading and writing tasks with respect to the recording disk; and
a housing arranged to accommodate the motor and the access unit.

17. A method for manufacturing a circuit board for supplying therethrough an electric current to a stator that includes windings arranged to generate magnetic fields for rotation of a motor, the circuit board including a body portion having a substantially rectangular shape when seen in a plan view and mounted with electronic parts and an extension portion protruding from the body portion along a circumferential direction around a rotation axis of the motor when seen in a plan view, the extension portion including a distal end extension opposed to the body portion through a gap when seen in a plan view, the transverse width of the extension portion as seen in a plan view being smaller than the gap, the body portion including an outward connector portion electrically connected to an external power source or an external circuit board, the extension portion including a winding connection portion connected to the outward connector portion through a wiring portion, the windings being soldered to the winding connection portion, the method comprising:
mounting a plurality of electronic parts on a parent board in which a plurality of circuit boards and a plurality of waste boards are connected into one piece by severance portions;
soldering the electronic parts to the circuit boards of the parent board; and
cutting the severance portions to sever the circuit boards carrying the electronic parts soldered thereto and the waste boards from the parent board.

18. The method of claim 17, wherein the circuit boards include a first circuit board and a second circuit board, the extension portion of the first circuit board being partially positioned in a gap through which the body portion and the extension portion of the second circuit board are opposed to each other.

19. The method of claim 17, wherein no resist ink is applied on the severance portions, naked portions applied with no resist ink being formed in a peripheral edge of the circuit boards by severing the severance portions.

20. The method of claim 17, wherein the severance portions are arranged to surround the circuit boards.
